(19) United States
(12) Patent Application Publication
(10) Pub. No.: US 2008/0076241 A1
(43) Pub. Date: Mar. 27, 2008

(54) Method for reducing stress between a conductive layer and a mask layer and use of the same

(75) Inventors: Tsung-Hsun Yang, Taichung City (TW); Hsiao-Che Wu, Jhongli City (TW); Feng-Chun Chen, Taichung City (TW); Chien-Hsun Pan, Taichung City (TW)

Correspondence Address: NIXON PEABODY LLP - PATENT GROUP, CLINTON SQUARE, P.O. BOX 31051, ROCHESTER, NY, 14603-1051, US

(73) Assignee: Promos Technologies Inc., Hsinchu (TW)

(21) Appl. No.: 11/641,131

(22) Filed: Dec. 19, 2006

(30) Foreign Application Priority Data
Sep. 27, 2006 (TW) 095135792

(51) Int. Cl. H01L 21/3205

(52) U.S. Cl. 438/585

(57) ABSTRACT

A method for reducing stress between a conductive layer and a mask layer is provided. The method for reducing stress comprises a step of performing a plasma treatment with a nitrogen-containing gas to modify a surface of the conductive layer prior to the formation of the mask layer upon the surface. The method is useful for the manufacture of a gate, and the method for manufacturing the gate comprises the steps of providing a substrate; and sequentially depositing an oxide layer, a conductive layer, and a mask layer on the substrate to form a gate stack structure. The conductive layer is subjected to a surface plasma treatment with a nitrogen-containing gas prior to depositing the mask layer to modify its surface.

This application benefits from the priority of Taiwan Patent Application No. 095135792 filed on Sep. 27, 2006.

### CROSS-REFERENCES TO RELATED APPLICATIONS

Not applicable

### BACKGROUND OF THE INVENTION

1. Field of the Invention

The present invention relates to a method of manufacturing a semiconductor device; in particular, the invention relates to a manufacturing method with the reduction of the stress between a conductive layer and a mask layer.

2. Descriptions of the Related Art

As integrated circuit technology progresses, the device's size also need to be smaller and thinner. Accordingly, with increased integration of the device, the circuit switching speed should also be sped up without increasing the power consumption of the device. For a metal-oxide-semiconductor field effect transistor (MOSFET), reducing the gate resistance may prevent signal delay resulting from resistance and capacitance, and thus, enhance the performance of the device.

A conventional gate structure comprises a gate oxide layer, a conductive layer, and a mask layer for protecting the conductive layer. To decrease the gate resistance, the conductive layer of the gate structure usually comprises a layer of doped polysilicide, and a layer of metal silicide or other metal. The metal (silicide) layer with low resistance is desired to decrease gate resistance and to improve the efficiency of the device. Furthermore, silicon nitride is normally used as the main material of the mask layer for effectively protecting the conductive layer during subsequent manufacturing process(es) such as a self-aligned contact etch process, and for isolating the gate conductive layer.

However, peeling between the conductive layer and the mask layer during the gate manufacturing processes always occurs, and seriously affecting the production yield. For example, the peeling may result in one to ten percentage yield loss or more during the manufacturing process(es) such as the double data rate synchronous dynamic random access memory (DDR SDRAM).

There are some conventional ways for reducing the aforementioned peelings between the conductive layer and the mask layer. For example: (1) conducting a rapid thermal annealing (RTA) under 750° C. after the deposition of the conductive layer; (2) conducting an RTA under 800° C. after the deposition of the conductive layer; (3) providing nitrogen and conducting a RTA under 800° C. after the deposition of the conductive layer; and (4) forming a buffer layer upon the conductive layer prior to the formation of the mask layer.

The aforementioned approaches, however, possess many shortcomings. Though the annealing process releases the internal stress accumulated in the materials, the annealing process is sensitive to the oxygen in the environment and the substrate. This sensitivity can compromise the stability and the reproducibility of the manufacturing process.

To reduce the peeling between the conductive layer and the mask layer of a gate, a simple technological solution which meets the aforementioned requirements and improves the production yield is highly desired in this field.

### SUMMARY OF THE INVENTION

An objective of this invention is to provide a method for reducing the stress between a conductive layer and a mask layer. The method comprises a plasma treatment with a nitrogen-containing gas to modify the surface of the conductive layer prior to the formation of the mask layer on the surface.

Another objective of this invention is to provide a method for manufacturing a gate. The method comprises the following steps: providing a substrate; and sequentially depositing an oxide layer, a conductive layer, and a mask layer on the substrate to form a gate stack structure, wherein the conductive layer is subjected to a surface plasma treatment with a nitrogen-containing gas prior to depositing the mask layer.

The detailed technology and preferred embodiments implemented for the subject invention are described in the following paragraphs accompanying the appended drawings for people with ordinary skills in this field to well appreciate the features of the claimed invention.

### BRIEF DESCRIPTION OF THE DRAWINGS

FIG. 1 shows a flow chart of an embodiment of the present invention;

FIG. 2A is a sectional view showing an embodiment of the present invention wherein a conductive layer surface of a gate structure is being modified; and

FIG. 2B shows a sectional view of an embodiment of the gate structure in accordance with the present invention.

### DESCRIPTION OF THE PREFERRED EMBODIMENT

Because the conventional ways did not provide efficient solutions for the peeling between the conductive layer and the mask layer of a gate structure, the inventors studied and analyzed the possible reasons for the peeling.

After studying embodiments wherein the conductive layer comprised tungsten silicide and the mask layer comprised silicon nitride, it was found that when the conductive layer and the mask layer were stacked, there were different stresses between the conductive layer and the mask layer, resulting in different degrees of peeling thereby. An actual statistical result showed that the peeling increased if the stress of the junction was 0 million Pascal. As the stress decreased to −100 million Pascal, the peeling decreased as well. If the stress decreased further to −200 million Pascal, there was an obvious decrease in peeling. That is, the peeling increases as the stress between the conductive layer and the mask layer increases. This relationship shows that the observed peeling may result from the stress generated from the material difference between the conductive layer and the mask layer.

Based on the aforementioned observations, the present invention provides a method for modifying the surface of the conductive layer to reduce the stress between the conductive layer and the mask layer, so as to eliminate the peeling between the conductive layer and the mask layer and enhance the yield of the gate manufacturing process.

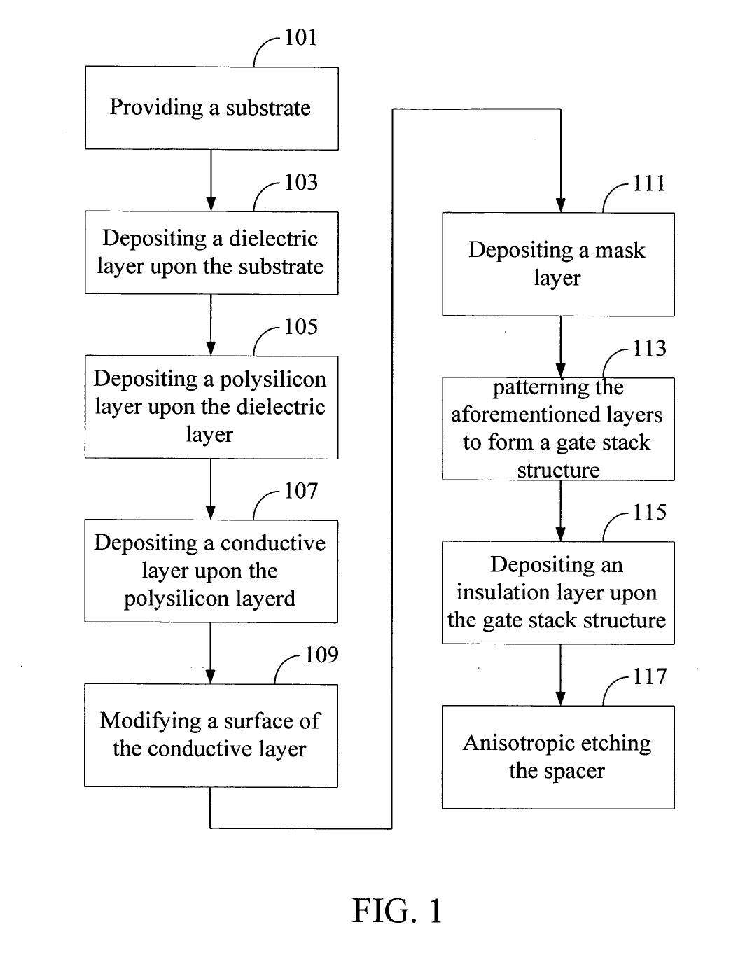

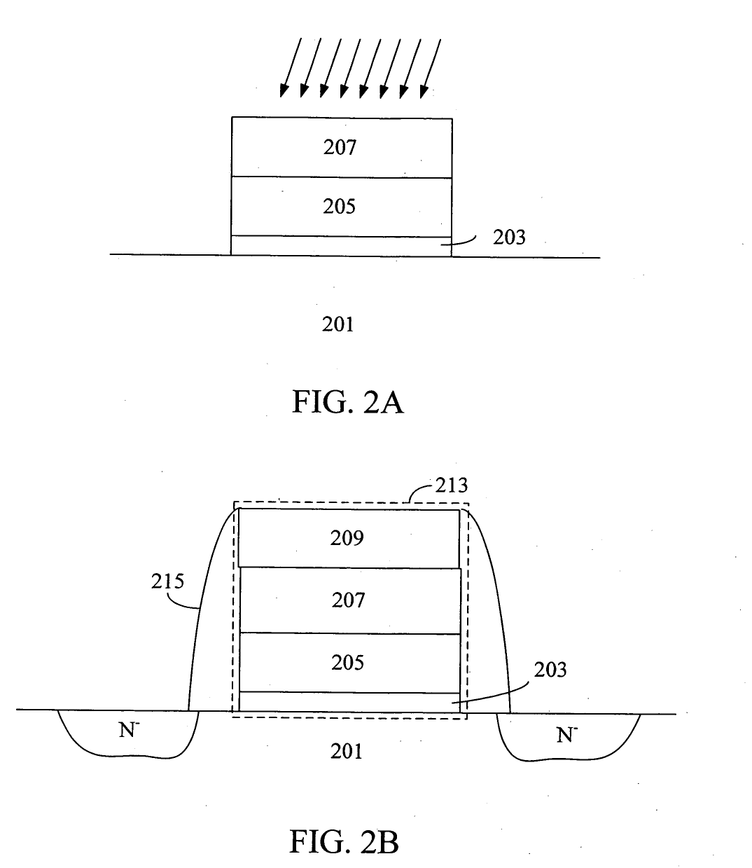

A method for manufacturing a gate is described below for illustrating the present invention in detail. FIG. 1 shows the flow chart of the method. As shown in FIG. 1, FIG. 2A and FIG. 2B, the method comprises the following steps. In step 101, a substrate 201 is provided. Then, in step 103, a dielectric layer 203 is deposited upon the substrate 201. Preferably, the dielectric layer 203 is, for example, but not limited to, an oxide layer, which can be formed by thermal oxidation. In step 105, a polysilicon layer 205 is formed on the dielectric layer 203. The polysilicon layer 205 can be deposited from the thermal dissociation of silane using low pressure CVD.

Then, in step 107, a conductive layer 207 is formed on the polysilicon layer 205. The conductive layer 207 is preferably a metallic layer. The conductive layer 207 can be, but not limited to, a tungsten metallic layer or a tungsten-containing layer such as a tungsten silicide layer. Taking the tungsten silicide layer as an example, the conductive layer 207 can be deposited from the reaction product of tungsten hexafluoride and silane by LPCVD.

Subsequently, in step 109, the surface of the conductive layer 207 is modified. In an embodiment, the treatment is proceeded by bombarding the surface with a nitrogen-containing plasma gas as shown in FIG. 2A. The nitrogen-containing gas can be selected from the group consisting of ammonia, nitrogen, and a combination thereof. Preferably, the nitrogen-containing gas is ammonia. Plasma formed from the nitrogen-containing gas under a power equal to or higher than 200 W is used to bombard the surface for 5 seconds or longer. Unlike the prior art required a thermal annealing process conducted at a temperature of 750° C. or higher, the present invention requires no thermal annealing process. The present invention also does not require a controlled temperature for the wafer substrate. Accordingly, the present invention reduces the thermal budget.

In step 111, a mask layer 209 is deposited. In an embodiment, the mask layer 209 is a dielectric layer such as, but not limited to, a silicon nitride layer. In step 113, the dielectric layer 203, the polysilicon layer 205, the conductive layer 207, and the mask layer are patterned to form a gate stack structure 213. In step 115, an insulation layer is deposited on the gate stack structure 213. Finally, in step 117, the insulation layer is anisotropically etched to form a spacer 215 at a side of the gate stack structure 213. A gate structure as shown in FIG. 2B is obtained thereby.

The following table shows a comparison between the numbers of defects and defect-containing dies of a first wafer that was not treated with the method of the present invention and those of a second wafer that was treated with the method of the present invention. The number of defects indicates the defects observed in the wafer. The number of defect-containing dies indicates the number of minimum operation unit areas with defects. As shown in the table, the first wafer had 270 defects and 170 defect-containing dies, whereas, the second wafer only had 60 defects and 21 defect-containing dies. Thus, the second wafer had fewer defects and defect-containing dies. Therefore, the peeling can be significantly eliminated by using the stress-reducing method of the present invention.

| Wafer | | | Defect-containing die |
|---|---|---|---|
| number | Condition | Defect number | number |
| 1^{st} wafer | Without treatment | 270 | 170 |
| 2^{nd} wafer | Treated with | 60 | 21 |
| | ammonia | | |

In conclusion, the present invention treats the tungsten silicide layer that is to be in contact with a silicon nitride mask layer. Accordingly, as a result of the reduced stress between the conductive layer and the mask layer, the peeling is prevented. In other embodiments where the conductive layer of the gate is metal, such as a tungsten layer, the aforementioned plasma process can also reduce the stress between the conductive layer and the mask layer. Therefore, with the gate manufacturing method of the present invention, the stress between the conductive layer and the mask layer would be decreased, the peeling between the conductive layer and the mask layer would be avoided, and the production yield of the semiconductor devices would be improved.

The sequence of the aforementioned steps for the manufacture of a gate is simply for illustration. Any gate manufacturing method being conceivable for people skilled in this art can adopt the method of the present invention to reduce the stress between the conductive layer and the mask layer to eliminate the peeling between the two layers.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A method for reducing stress between a conductive layer and a mask layer, the method comprising performing a plasma treatment with a nitrogen-containing gas to modify a surface of the conductive layer prior to the formation of the mask layer upon the surface.

2. The method as claimed in claim 1, wherein the conductive layer is a metallic layer.

3. The method as claimed in claim 2, wherein the metallic layer is a tungsten-containing layer.

4. The method as claimed in claim 3, wherein the tungsten-containing layer is a tungsten silicide layer.

5. The method as claimed in claim 1, wherein the mask layer is a dielectric layer.

6. The method as claimed in claim 5, wherein the dielectric layer is a silicon nitride layer.

7. The method as claimed in claim 1, wherein the nitrogen-containing gas is selected from a group consisting of ammonia, nitrogen, and the combination thereof.

8. The method as claimed in claim 1, wherein the plasma treatment is proceeded under a power equal to or higher than 200 W.

9. The method as claimed in claim 1, wherein the plasma treatment is proceeded for 5 seconds or longer

10. A method for manufacturing a gate, comprising:
providing a substrate; and
sequentially depositing an oxide layer, a conductive layer, and a mask layer on the substrate to form a gate stack structure;
wherein a surface of the conductive layer is subjected to a surface plasma treatment with a nitrogen-containing gas prior to depositing the mask layer to modify the surface.

11. The method as claimed in claim 10, wherein the conductive layer is a metallic layer.

12. The method as claimed in claim 11, wherein the metallic layer is a tungsten-containing layer.

13. The method as claimed in claim 12, wherein the tungsten-containing layer is a tungsten silicide layer.

14. The method as claimed in claim 10, wherein the mask layer is a dielectric layer.

15. The method as claimed in claim 14, wherein the dielectric layer is a silicon nitride layer.

16. The method as claimed in claim 10, wherein the nitrogen-containing gas is selected from a group consisting of ammonia, nitrogen, and the combination thereof.

17. The method as claimed in claim 10, wherein the plasma treatment is proceeded under a power equal to or higher than 200 W.

18. The method as claimed in claim 10, wherein the plasma treatment is proceeded for 5 seconds or longer

19. The method as claimed in claim 10, wherein the formation of a gate stack structure further comprises depositing a polysilicon layer prior to depositing the conductive layer.

20. The method as claimed in claim 10, further comprising a step of forming a spacer at a side of the gate stack structure after the step of forming a gate stack structure.
